(19) United States
(12) Patent Application Publication
(10) Pub. No.: US 2013/0208254 A1
(43) Pub. Date: Aug. 15, 2013

(54) NANO-PHOTOLITHOGRAPHIC SUPERLENS DEVICE AND METHOD FOR FABRICATING SAME

(71) Applicants: Hong Liu, Singapore (SG); Jinghua Teng, Singapore (SG); Lin Ke, Singapore (SG); Bing Wang, Singapore (SG)

(72) Inventors: Hong Liu, Singapore (SG); Jinghua Teng, Singapore (SG); Lin Ke, Singapore (SG); Bing Wang, Singapore (SG)

(73) Assignee: AGENCY FOR SCIENCE, TECHNOLOGY AND RESEARCH, Singapore (SG)

(21) Appl. No.: 13/588,058

(22) Filed: Aug. 17, 2012

Related U.S. Application Data
(60) Provisional application No. 61/524,347, filed on Aug. 17, 2011.

(51) Int. Cl. G03F 7/20

(52) U.S. Cl. CPC G03F 7/2014
USPC 355/71; 427/162; 216/26; 427/585

(57) ABSTRACT

A system for nano-photolithography, a superlens device, and a method for fabricating the superlens device. A system for three-dimensional nano-photolithography includes a light source having a predetermined light wavelength, a device to be patterned, a photoresist layer of photoresponsive material photoresponsive to the predetermined light wavelength formed on the device, and a superlens device in contact with the photoresist layer. The superlens device includes a superlens layer in contact with the photoresist layer, a light permissive mask layer transparent to the predetermined light wavelength and having a layer of nanopatterned opaque features formed thereon, and an intermediate layer separating the superlens layer and the light permissive mask layer by a predetermined distance. The light source is located to radiate light at the predetermined light wavelength on the light permissive mask layer. The layer of nanopatterned opaque features includes a layer of opaque features with varying height dimensions.

### CROSS-REFERENCE TO RELATED APPLICATION

The present application claims priority to U.S. Patent Application No. 61/524,347, filed 17 Aug. 2011 which is incorporated by reference herein in its entirety.

### FIELD OF THE INVENTION

The present invention generally relates to nano-photolithography systems, and more particularly relates to superlens devices for nano-photolithography systems, method for fabrication of such superlens devices, and nano-photolithography system using such superlens devices.

### BACKGROUND

Conventional projection photolithography systems, which are equipped with such conventional lenses, have been widely used in laboratories and in the semiconductor industry. The image resolution obtained by a conventional optical lens, however, is fundamentally limited by diffraction to approximately half of the wavelength of the light used, this limitation known as Abbe's Limit. Also, even though the resolution of a photomask could be very high, such projection photolithography setups unfortunately still suffer from this light diffraction limit when attempting to meet small size requirements.

With the advance of nanotechnology and increasing demand from various real nanotechnology applications, low-cost and high-throughput, as well as ultrahigh resolution nanofabrication techniques have become highly desirable. Currently, there are a few nanolithography techniques which have been well developed or commercially available. For example, electron beam lithography (EBL), focused ion beam (FIB) milling, x-ray lithography and dip pen lithography (DPN) are currently able to produce high-resolution nanoscale patterns. However, these techniques and the tools necessary to implement them are costly and their throughputs are very low in terms of large-scale patterning.

Nanosphere lithography (NSL) offers a low-cost method of nano-patterning and fabrication of nanostructures for the semiconductor industry and for biological and chemical analysis. NSL techniques create nanostructure arrays utilizing planar ordered nanosphere arrays as a mask. Dielectric nanospheres employed in NSL exhibit interesting optical properties, which makes NSL frequently used method for plasmonic studies. However, the shapes of NSL patterns are restricted due to nanosphere arrays being directly formed on substrate surface. Further, NSL is not applicable to many substrate materials because of the different surface properties of substrate materials. Agglomerations of nanoparticles after metal deposition are frequently a result of dislocation of nanospheres during formation of the nanosphere monolayer, thereby hindering successful lift-off of the nanosphere monolayer. These limitations make NSL only feasible for limited, specified applications.

Nanoimprinting lithography (NIL) is also a promising, effective technique for large-scale surface patterning in nanoscale. NIL offers a lower cost and higher throughput in comparison with the aforementioned nanolithography techniques. In addition, it also exhibits high resolution patterning and great flexibility in accommodating a large variety of polymer materials. These advantages make NIL tend to be an effective supplementary tool for nanofabrication of semiconductors, MEMS/NEMS devices, chemical and biological templates. Compared to commonly used projection photolithography systems in semiconductor industry, the throughput of step nanoimprinting for large area patterning is still not as high as photolithography. Some other issues related to NIL such as resist and template properties, relative complex process, accuracy and defect control also still need further investigation.

Thus, what is needed is a scalable, easily integratable nanopatterning solution for two-dimensional and three-dimensional subwavelength nanopatterning that can provide high throughput at a low cost. Furthermore, other desirable features and characteristics will become apparent from the subsequent detailed description and the appended claims, taken in conjunction with the accompanying drawings and this background of the disclosure.

### SUMMARY

According to the Detailed Description, a nano-photolithographic superlens device is provided. The nano-photolithographic superlens device includes a light permissive mask layer, a nanopatterned layer of opaque features formed on the mask layer, an intermediate layer formed on the nanopatterned layer and the mask layer, and a superlens layer formed on the intermediate layer. The intermediate layer has a predetermined thickness and is index matched to the superlens layer.

In accordance with another aspect, a method for fabrication of a nano-photolithographic superlens device is provided. The method includes the steps of providing a light permissive mask layer and forming a nanopatterned layer of opaque features on the mask layer. The method further includes the steps of forming an intermediate layer on the nanopatterned layer and the mask layer and forming a superlens layer on the intermediate layer, wherein roughness of the intermediate layer is controlled during its formation in order to provide a smooth superlens layer.

And in accordance with a further aspect, a system for nano-photolithography is provided. The system for nano-photolithography includes a light source having a predetermined light wavelength, a device to be patterned, and a photoresist layer of photoresponsive material formed on the device. The photoresponsive material is photresponsive to the predetermined light wavelength. The system further includes a superlens device in contact with the photoresist layer and including a superlens layer, a light permissive mask layer, and an intermediate layer. The superlens layer is in contact with the photoresist layer. The light source is located to radiate light at the predetermined light wavelength on the light permissive layer, the light permissive mask layer being transparent to the predetermined light wavelength. The light permissive layer also has a layer of nanopatterned opaque features formed thereon. And the intermediate layer is located between the superlens layer and the light permissive mask layer to separate them by a predetermined distance.

### BRIEF DESCRIPTION OF THE DRAWINGS

The accompanying figures, where like reference numerals refer to identical or functionally similar elements throughout the separate views and which together with the detailed description below are incorporated in and form part of the specification, serve to illustrate various embodiments and to explain various principles and advantages disclosed herein.

FIG. 1, including FIGS. 1A and 1B, illustrates a side planar view of a nano-photolithographic system utilizing a superlens device in accordance with the present embodiment.

FIG. 2, including FIGS. 2A to 2C, illustrates steps of a method of fabricating the nano-photolithographic superlens device of FIG. 1 in accordance with the present embodiment.

FIG. 3, including FIGS. 3A and 3B, depict two-dimensional nano-photolithography results of the system of FIG. 1 in accordance with the present embodiment, where FIG. 3A depicts patterning resulting from the two-dimensional nano-photolithography and FIG. 3B is a graph of normalized profiles of object and pattern resulting from the two-dimensional nano-photolithography.

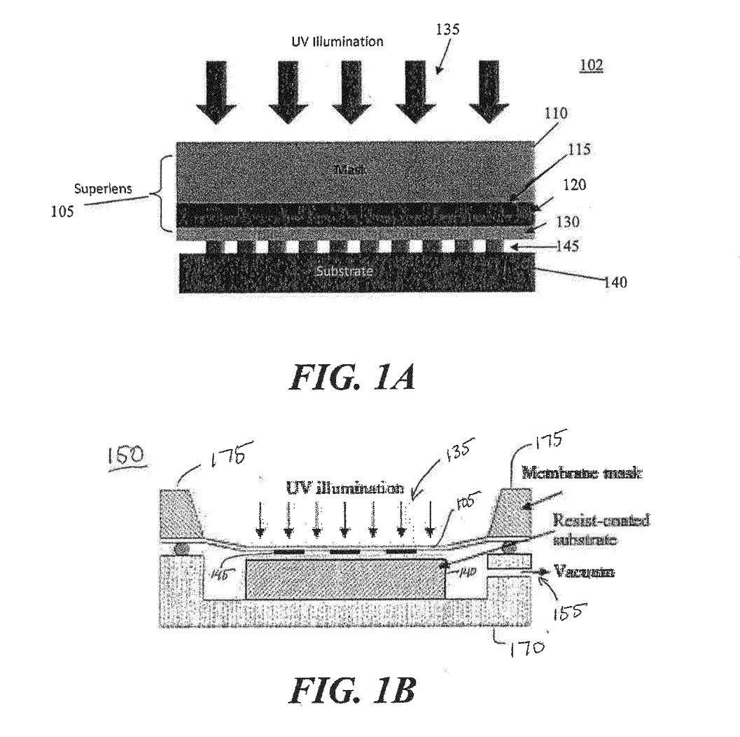

And FIG. 4, including FIGS. 4A to 4C, depict three-dimensional nano-photolithography results of the system of FIG. 1 in accordance with the present embodiment, where FIG. 4A is a planar view depicting patterning resulting from the three-dimensional nano-photolithography, FIG. 4B is a perspective view depicting the patterning resulting from the three-dimensional nano-photolithography with a graph and a cutaway view of the three-dimensionality, and FIG. 4C is a graph of surface modulation of the three-dimensional object and the photoresist patterning resulting from the three-dimensional nano-photolithography.

Skilled artisans will appreciate that elements in the figures are illustrated for simplicity and clarity and have not necessarily been depicted to scale. For example, the dimensions of some of the elements in the figures illustrating the superlens device may be exaggerated in one dimension relative to another dimension to help to improve understanding of the present and alternate embodiments. In addition the planar and perspective views of FIGS. 4A, 5A and 5B are highly magnified views of nanoscale patterning resulting from use of the nano-photolithography system in accordance with the present embodiment.

### DETAILED DESCRIPTION

The following detailed description is directed to various embodiments of the invention. Although one or more of these embodiments may be preferred, the embodiments disclosed should not be interpreted, or otherwise used, as limiting the scope of the disclosure, including the claims. Furthermore, there is no intention to be bound by any theory presented in the preceding background or the following detailed description. It is the intent of this disclosure to present a nano-photolithographic technology using contact optical lithography and taking advantage of the superlens effect to achieve both two-dimensional and three-dimensional nanopatterning with super-resolution and good fidelity.

Projection optical lithography has become the main lithography technology employed for high-volume semiconductor manufacturing. However, projection optical lithography is a far-field optical imaging process which has a fundamental resolution limit of λ/2, where λ is the wavelength of the light projected. Contact optical lithography is an alternative lithographic technology and by its nature is a near-field optical imaging process. By bringing the mask into contact with the photoresist layer, there is effectively no space for light waves to travel between the mask opening and the photoresist layer, except within the photoresist layer. Therefore, light waves no longer propagate as sinusoidal waves but as evanescent waves. So, such contact optical lithography can also be termed evanescent near-field optical lithography.

Thus, the sinusoidal propagating waves of scattering light from an object carry large feature information while the evanescent waves carry fine feature (subwavelength) information. The evanescent waves decay exponentially when traveling in any positive refractive index medium, which is accountable for the diffraction-limited images obtained by conventional optical lenses. A superlens is superior to conventional lenses and is able to enhance evanescent waves passing through its negative-refractive-index material, thereby creating a perfect image in either near-field or far-field by recovering a combination of evanescent and propagating waves in an image plane.

Referring to FIG. 1A, a diagram 102 illustrates a side planar view of a superlens device 105 operating in a nano-photolithographic system in accordance with a present embodiment. The superlens device 105 includes a light permissive mask layer 110 with a nanopatterned layer 115 formed thereon. The nanopatterned layer 115 includes patterned opaque nanoscale features such as parallel nanopatterned stripes of chrome or similar opaque materials. An intermediate layer 120 acts as a spacer between the mask layer 110 and a superlens layer 130.

Light 135 of a predetermined wavelength, such as ultraviolet (UV) light, is radiated from a light source (not shown) onto the superlens device 105, passing through the light permissive mask layer 110, the nanopatterned layer 115 and the intermediate layer 120 to strike the superlens layer 130. The superlens layer 130 is formed of a material having a negative refractive index (and consequently a negative permittivity) such as silver, gold or palladium and when the radiated light 135 strikes the superlens layer 130, evanescent waves are scattered and a combination of evanescent and propagating waves from the light 135 are recovered in an image plane at a substrate 140 having a patterned photoresist layer 145 formed thereon.

As seen in FIG. 1B, an exemplary nano-photolithographic system 150 in accordance with the present embodiment places the superlens device 105 in hard contact with the photoresist-coated substrate 140, 145 or other device to be patterned under a vacuum 155. In the depicted system 150, the superlens device 105 may be a conformable membrane or supported on a conformable membrane 160. The vacuum 155 is maintained underneath the membrane 160 by a housing 170, including portions 175 for pinning the top of the membrane 160 to a lower portion of the housing 170. In this manner, the housing 170 (including portions 175), the vacuum 155, and the conformable membrane 160 act as a mask aligner to align the superlens device 105 with the photoresist-coated substrate 140, 145 while maintaining it in hard contact with the photoresist layer 145 for undergoing the photolithography process. Those skilled in the photolithographic arts will realize that the system 150 depicted in FIG. 1B is merely exemplary and the present embodiment allows for a scalable process implementable in high throughput semiconductor fabrication processes.

In accordance with the present embodiment, the subwavelength patterning is improved and optimized by permittivity index matching between the intermediate layer 120, the superlens layer 130 and the photoresist 145. Index matching refers to the intermediate layer 120 having a permittivity substantially equal to the absolute value of the permittivity of the superlens layer 130 and the photoresist 145 at the predetermined light wavelength of the light 135 from the light source. The index matching of the permittivity of the intermediate layer 120, the superlens layer 130 and the photoresist 145 at the wavelength of the light 135 eliminates the waveguide effect well-known to those skilled in the art and the negative permittivity (and, hence, the negative refractive index) enhances evanescent waves passing therethrough, thereby creating a perfect image in either near-field or far-field by recovering a combination of evanescent and propagating waves in an image plane of the photoresist 145. Without index matching of these layers, the superlens effect would be greatly deteriorated and sub-diffraction-limit patterning would be highly difficult. Thus, it can be seen that the thin flat superlens device 105 in accordance with the present embodiment enhances evanescent wave scattering across it to achieve subwavelength patterning using common photolithography processes.

In addition to index matching, in accordance with various embodiments of the invention, the vacuum-assisted hard contact between the superlens device 105 and the photoresist layer 145 is improved by providing a smooth surface on the superlens layer 130. This improved smooth surface is maintained has a smoothness predetermined to be a root-mean-square (rms) surface roughness of less than three nanometers, which is facilitated by fabricating the intermediate layer to have an rms surface roughness of less than five nanometers.

The light permissive mask layer 110 is formed of a material transparent to the wavelength of the light 135 (e.g., UV light) such as quartz or soda lime. The opaque features 115 formed on the mask layer 110 are preferably formed of chrome (i.e., comprising chromium) and, in accordance with the present embodiment have the widths thereof and the distance between adjacent features predetermined in response to the wavelength of the light 135. Further, in accordance with the present embodiment, the intermediate layer 120 is formed of a polymer material, a dielectric material, a composite material or an organic material and preferably has a thickness between 0.1 nanometers and 100 nanometers. Additionally, the superlens layer 130 preferably has a thickness between 1 nanometer and 100 nanometers.

In accordance with another aspect of the present embodiment, three-dimensional nano-photolithography is made possible by adjusting parameters of the patterned opaque nanoscale features of the nanopatterned layer 115 formed on the mask layer 110. When all of the patterned opaque nanoscale features have consistent heights, two-dimensional nano-photolithography is performed. By varying heights for each of the opaque features, three-dimensional nano-photolithography is achievable.

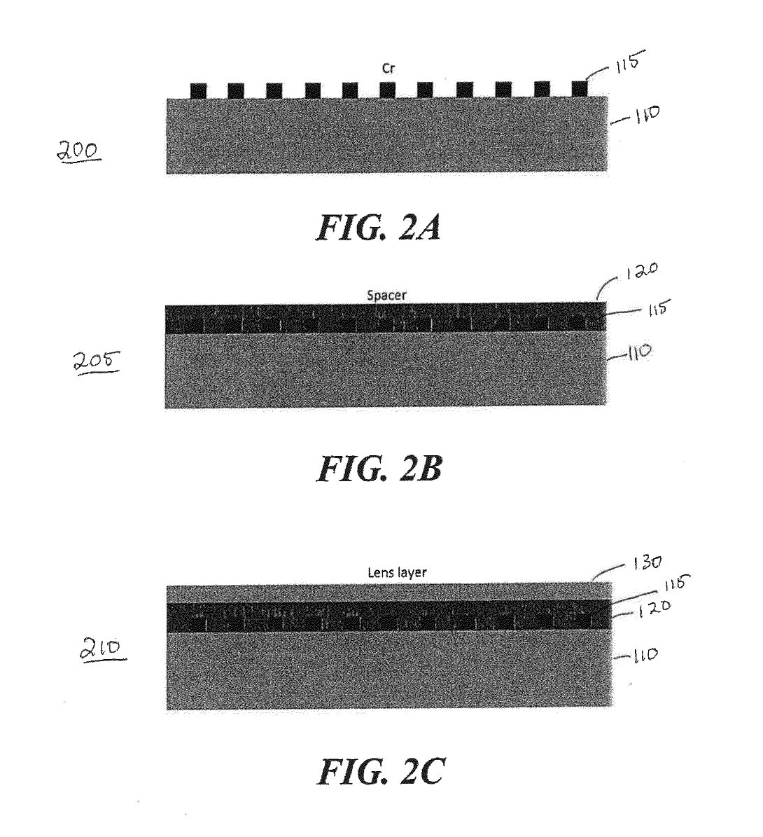

Referring to FIG. 2A, method of fabricating the nano-photolithographic superlens device 105 in accordance with the present embodiment begins at mask fabrication step 200 by forming the patterned opaque nanoscale features of the nanopatterned layer 115 on the mask layer 110. Initially, a chromium layer is deposited by, for example, electron-beam evaporation onto the mask layer 110 (e.g., a quartz substrate) to a depth of approximately forty nanometers. A nano-grating of a predetermined feature size is then patterned by electron beam lithography onto photoresist deposited over the chromium layer. The dimensions of the feature size are predetermined in response to the wavelength of the light 135 (FIG. 1B). For example, a line width of 75 nanometers separated by a space between adjacent lines of 45 nanometers would correspond to feature sizes predetermined in response to a 365 nm wavelength of ultraviolet light. The photoresist pattern is then transferred into the chromium layer to form the nanopatterned layer 115 by ion milling at a predetermined power (e.g., about 200 W) for a predetermined time (e.g., several minutes), followed by resist stripping the patterned photoresist to finalize the mask fabrication step 200.

After the mask fabrication step 200, a planarizing step 205 is performed to planarize the nanopatterned layer 115. Referring to FIG. 2B, the planarizing step 205 is shown. The intermediate layer 120 of a material having an index of permittivity matching the material chosen for the superlens layer 130 (FIG. 1A) at the wavelength of the light 135 (FIG. 1A) (e.g., silver at 365 nanometers UV light) is deposited on top of the nanopatterned layer 115 and the mask layer 110 (by, for example, multiple-step spin-coating) to get an initial thickness greater than the nanopatterned layer 115. Etching (by, for example, oxygen plasma etching) is then applied to etch the intermediate layer 120 down to a thickness greater than the nanopatterned layer 115 (and preferably between 0.1 nanometers and 100 nanometers) to, for example, about 20 nanometers. A reflow process is next performed to make the surface of the intermediate layer 120 as smooth as possible, and preferably having a smoothness predetermined to be a root-mean-square (rms) surface roughness of less than five nanometers.

Referring next to FIG. 2C, a superlens formation step 210 is depicted. A film of negative refractive index material is deposited on the intermediate layer 120 to a depth of between 1 nanometer and 100 nanometers (e.g., to a depth of 35 nanometers) to form the superlens layer 130. Deposition in the superlens formation step 210 can be performed by electron-beam evaporation or other metallic deposition methods known to those skilled in the art. As the superlens layer 130 is formed by deposition over the super smooth intermediate layer 120, the superlens layer will also be super smooth, preferably having a smoothness predetermined to be an rms surface roughness of less than three nanometers.

Also, as mentioned above in regards to the planarizing step 205, the material of the superlens layer 130 and the material of the intermediate layer 120 are index matched by selecting the intermediate layer 120 material to have a permittivity substantially equal to the absolute value of the permittivity of the superlens layer 130 material at the wavelength of the light 135 (FIG. 1A).

In accordance with the present embodiment, three-dimensional nano-photolithography can be enabled by altering the mask fabrication step 200. If heights of the patterned opaque nanoscale features of the nanopatterned layer 115 are formed to have consistent heights, two-dimensional nano-photolithography will be performed when using the superlens device 105 in accordance with the present embodiment. On the other hand, three-dimensional nano-photolithography will be performed when using the superlens device 105 in accordance with the present embodiment if heights for each of the patterned opaque nanoscale features of the nanopatterned layer 115 are varied during formation. One method for varying the heights for each of the opaque features of the nanopatterned layer 115 during formation in accordance with the present embodiment is varying loading (such as power loading for ion milling) across the nanopatterned layer 115 during etching to achieve different heights of the opaque features.

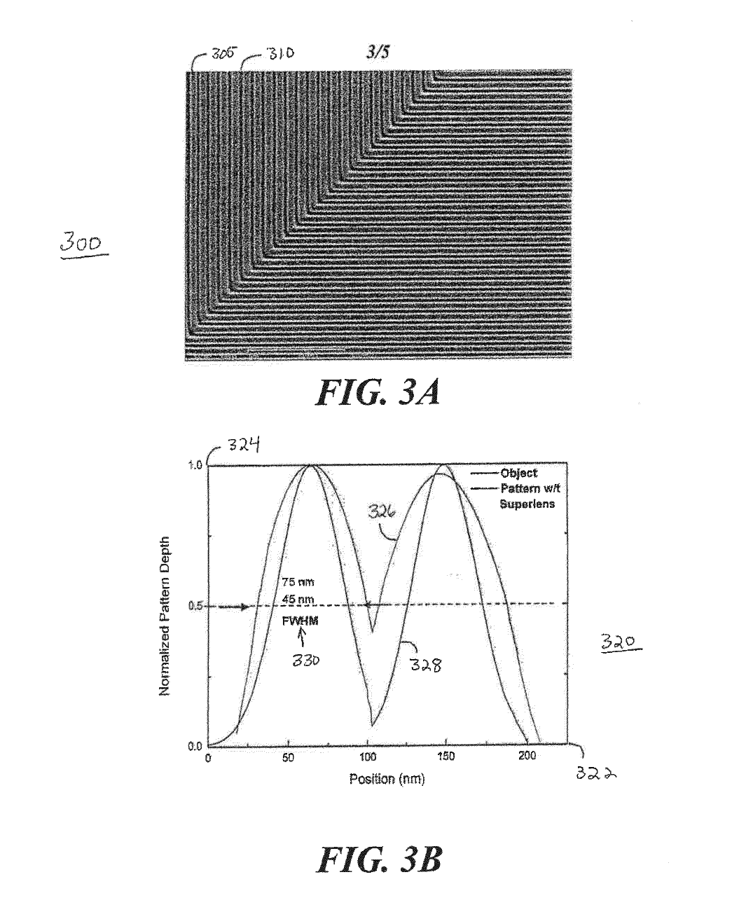

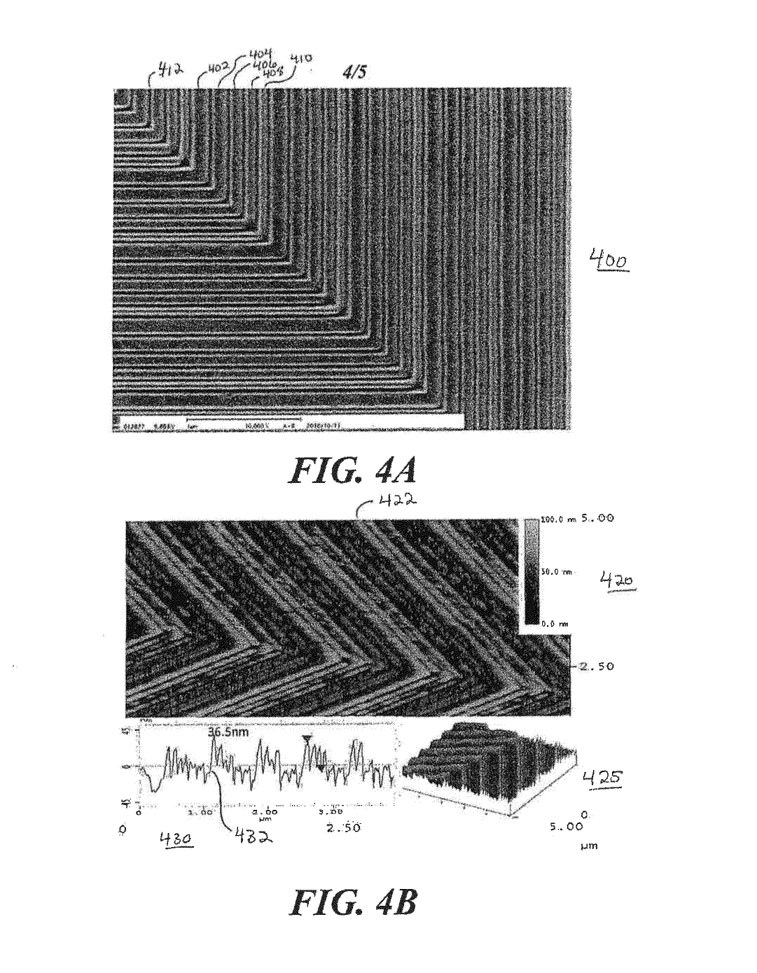

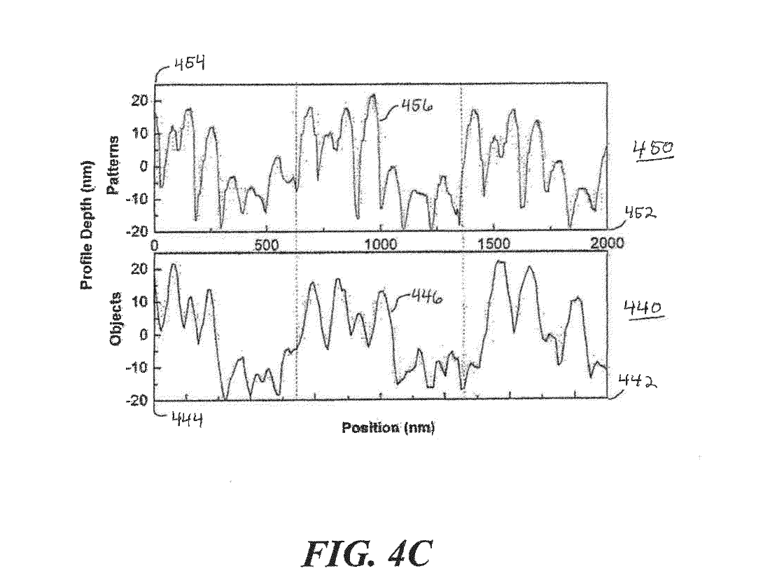

Referring to FIGS. 3A and 3B, a two-dimensional nano-photolithography system and results of the nano-photolithographic system in accordance with the present embodiment are depicted. FIG. 3A depicts patterning of the nanopatterned layer 115 for two-dimensional nano-photolithography in accordance with the present embodiment. And FIG. 3B is a graph of normalized profiles of the nanopatterned layer 115 and a nano-photolithographed pattern resulting from the nano-photolithographic system in accordance with the present embodiment.

In regards to FIG. 3A, a scanning electron microscope (SEM) picture 300 of the nanopatterned layer 115 for two-dimensional nano-photolithography in accordance with the present embodiment is depicted. The chrome opaque features 305 in the picture 300 have a 75 nanometer line width and the separation 310 between adjacent features 305 is 45 nanometers.

In regards to FIG. 3B, a graph 320 of normalized two-dimensional profiles of object features 305 and pattern formed with the superlens device 105 in accordance with the present embodiment as scanned by an atomic force microscope (AFM) is depicted. To obtain the pattern formed with the superlens device 105, a 100-nanometer-thick layer of negative photoresist 145 was spin-coated onto a substrate and the superlens device 105 was vacuum-assisted into hard contact with the photoresist 145. Ultraviolet light 135 at I-line (365 nm) was then radiated on the superlens device 105 from the light permissible mask 110 side and the pattern was obtained by post-bake at 120° C. for five minutes followed by photoresist development.

Along the x-axis 322 of the graph 320, position is plotted while normalized pattern depth is plotted along the y-axis 324. Thus, the plotting of normalized depth profile vs. position for the photoresist pattern on trace 326 and for the object features 305 on trace 328 show that nano-photolithography in accordance with the present embodiment using the superlens device 105 advantageously achieves an unprecedented sub-diffraction-limited pattern. Furthermore, the full width at half maximum (FWHM) 330 of the cross-section curve, which corresponds to the resolution of superlens device 102, has been measured at about 75 nanometers. Thus it can be seen that the superlens device 105 in accordance with the present embodiment is able to transfer 45 nanometer wide gratings of 60-nanometer half-pitch.

Referring next to FIG. 4, including FIGS. 4A to 4C, surface characterization of the superlens device in accordance with the present embodiment is illustrated with chrome opaque features of varying line widths and varying heights. FIG. 4A depicts a SEM picture 400 of opaque features 402, 404, 406, 408 and 410 with respective 40, 60, 80, 100 and 120 nanometer line widths separated by a distance 412 of approximately 60 nanometers, the period of which is about 700 nanometers. During etching of the opaque features by ion milling, the loading effect was varied causing different etch rates for identical features depending on their relative position to open area features, thereby transforming the two-dimensional photoresist patterns on the chrome into three-dimensional chrome patterns. After ion milling, height differences varying from several nanometers to more than 40 nanometers were created on the opaque features 402, 404, 406, 408 and 410.

FIG. 4B depicts an AFM image 420 of the three-dimensional surface topography of the photoresist 422 transferred from the opaque features 402, 404, 406, 408 and 410 after the nano-photolithography process. Inset 425 depicts a three-dimensional perspective view of the AFM image 420 of the scanned area and inset 430 illustrates a cross-sectional plot 432. The plot 432, the inset perspective view 425 and the variation in color in the AFM image 420 clearly show the three-dimensional surface topography of the photoresist 422 as patterned by the opaque features 402, 404, 406, 408 and 410 of the superlens device 105 during the nano-photolithography process

FIG. 4C are two graphs 440, 450 depicting profile depth vs. position of the three-dimensional opaque features 402, 404, 406, 408 and 410 (in graph 440) and the patterned photoresist 422 (in graph 450). Along the x-axes 442, 452, the position is plotted and along the y-axes 444, 454 the profile depth is plotted. A comparison of profile depth trace 456 for the patterned photoresist 422 to the profile depth trace 446 for the three-dimensional opaque features 402, 404, 406, 408 and 410 reflects a good fidelity between surface topographies has been achieved in accordance with the present embodiment.

Thus, operation in accordance with the present embodiment achieves object-to-pattern resolution and fidelity much greater than prior art nano-patterning solutions. In addition, the overall design and fabrication process are completely compatible with existing semiconductor processes, making this a highly scalable, easily integratable nano-photolithographic solution. Further, the superlens device provides a robust solution for large scale fabrication (up to 12-inch wafer) of two-dimensional and three-dimensional nanostructures, which makes it extremely attractive and promising in nano-patterning applications for its low cost, high throughput and super resolution.

Index-matching between the spacer (intermediate layer 120), the superlens layer 130 and the photoresist 145 at the wavelength of the light 135 provides beneficial nano-photolithography in accordance with the present embodiment. The surface smoothness of the intermediate layer 120 and the superlens layer 130 further facilitate the subwavelength patterning in accordance with the present embodiment. The superlens device 105 design and the fabrication process in accordance with the present embodiment are simple and can be immediately integrated with existing projection photolithography systems for fabrication of two-dimensional and three-dimensional nanoscale patternings.

Accordingly, a superlens device 105 which is able to achieve super-resolution, two-dimensional and three-dimensional sub-diffraction-limit patterning by normal photolithography system, has been presented. Utilizing negative-refractive-index superlens layer 130 deposited on a smooth index-matching intermediate layer 120 to form the flat optical superlens device 105, the evanescent waves carrying the fine feature information of light scattered from opaque feature objects 115 will be enhanced to create super resolution sub-diffraction-limited patterns in the near field. The method can be extended to any existing photolithography equipment and presents a high throughput, low cost, competitive technology for nano-patterning. While several exemplary embodiments have been presented in the foregoing detailed description, it should be appreciated that a vast number of variations exist, including variations as to the materials and shapes used to form the various layers and structures 110, 115, 120, 130, 145.

It should further be appreciated that the exemplary embodiments are only examples, and are not intended to limit the scope, applicability, dimensions, or configuration of the invention in any way. Rather, the foregoing detailed description will provide those skilled in the art with a convenient road map for implementing an exemplary embodiment of the invention, it being understood that various changes may be made in the function and arrangement of elements and method of fabrication described in an exemplary embodiment without departing from the scope of the invention as set forth in the appended claims.

What is claimed is:

1. A nano-photolithographic superlens device comprising:
a light permissive mask layer;
a nanopatterned layer of opaque features formed on the mask layer;
an intermediate layer formed on the nanopatterned layer and the mask layer, the intermediate layer having a predetermined thickness; and
a superlens layer formed on the intermediate layer,
wherein the intermediate layer is index matched to the superlens layer.

2. The device in accordance with claim 1 wherein the light permissive mask layer comprises materials selected from the group of materials consisting of quartz, soda lime, and other materials transparent to predetermined light wavelengths of a light source.

3. The device in accordance with claim 2 wherein widths of the opaque features of the nanopatterned layer are predetermined in response to the predetermined light wavelengths of the light source.

4. The device in accordance with claim 2 wherein distances between adjacent opaque features of the nanopatterned layer are predetermined in response to the predetermined light wavelengths of the light source.

5. The device in accordance with claim 2 wherein the intermediate layer is index matched to the superlens layer by the intermediate layer having a permittivity substantially equal to the absolute value of the permittivity of the superlens layer at the predetermined light wavelengths of the light source.

6. The device in accordance with claim 2 wherein the superlens layer comprises materials selected from the group of materials consisting of gold, silver, platinum, palladium, engineered materials having a negative refractive index at the predetermined light wavelengths of the light source, and engineered materials having a negative permittivity at the predetermined light wavelengths of the light source.

7. The device in accordance with claim 1 wherein heights of the opaque features of the nanopatterned layer comprise one of consistent heights or varying heights, wherein consistent heights for all of the opaque features enables two-dimensional nano-photolithography, and wherein varying heights for each of the opaque features enables three-dimensional nano-photolithography.

8. The device in accordance with claim 1 wherein the opaque features comprise chromium.

9. The device in accordance with claim 1 wherein the intermediate layer comprises materials selected from the group of materials consisting of a polymer material, a dielectric material, a composite material and an organic material.

10. The device in accordance with claim 1 wherein the predetermined thickness of the intermediate layer comprises a thickness selected from the thicknesses between 0.1 nanometers and 100 nanometers.

11. The device in accordance with claim 1 wherein the intermediate layer has a root-mean-square (rms) surface roughness of less than five nanometers.

12. The device in accordance with claim 1 wherein the superlens layer has a thickness selected from the thicknesses between 1 nanometer and 100 nanometers.

13. The device in accordance with claim 1 wherein the superlens layer has a root-mean-square (rms) surface roughness of less than three nanometers.

14. A method for fabrication of a nano-photolithographic superlens device comprising the steps of:
providing a light permissive mask layer;
forming a nanopatterned layer of opaque features on the mask layer;
forming an intermediate layer on the nanopatterned layer and the mask layer; and
forming a superlens layer on the intermediate layer,
wherein roughness of the intermediate layer is controlled during formation thereof in order to provide a smooth superlens layer.

15. The method in accordance with claim 14 wherein the step of forming the intermediate layer comprises:
forming the intermediate layer to a predetermined thickness; and
reflowing the intermediate layer until the intermediate layer has a root-mean-square (rms) surface roughness of less than five nanometers.

16. The method in accordance with claim 15 wherein the step of forming the intermediate layer to the predetermined thickness step comprises forming the intermediate layer by a process selected from the group of processes consisting of spin-coating material to the predetermined thickness, spin-coating material to greater than the predetermined thickness followed by etching the material back to the predetermined thickness and depositing material to greater than the predetermined thickness followed by etching the material back to the predetermined thickness.

17. The method in accordance with claim 14 wherein the step of forming the nanopatterned layer comprises:
depositing opaque material;
deposit resist having a nanograting pattern on the opaque material;
etching the opaque material through the nanograting pattern of the resist to form the opaque features of the nanopatterned layer; and
stripping the resist from the nanopatterned layer.

18. The method in accordance with claim 17 wherein the step of depositing the opaque material comprises depositing the opaque material by e-beam evaporation.

19. The method in accordance with claim 17 wherein the step of depositing the resist having the nanograting pattern comprises:
depositing a layer of the resist on the opaque material; and
forming the nanograting pattern in the layer of the resist by e-beam lithography.

20. The method in accordance with claim 17 wherein the step of etching the opaque material through the nanograting pattern of the resist comprises ion milling etching the opaque material through the nanograting pattern of the resist to form the opaque features of the nanopatterned layer.

21. The method in accordance with claim 20 wherein the step of ion milling the opaque material comprises varying loading across the nanopatterned layer during ion milling to achieve different heights of the opaque features to enable three-dimensional nano-photolithography.

22. The method in accordance with claim 14 wherein the step of forming the superlens layer comprises depositing negative refractive index material on the intermediate layer to form the superlens layer.

23. The method in accordance with claim 22 wherein the step of depositing the negative refractive index material comprises electron-beam evaporation deposition of the negative refractive index material as a film on the intermediate layer.

24. A system for three-dimensional nano-photolithography comprising:
a light source having a predetermined light wavelength;
a device to be patterned;
a photoresist layer of photoresponsive material formed on the device, wherein the photoresponsive material is photoresponsive to the predetermined light wavelength; and
a superlens device in contact with the photoresist layer, the superlens device comprising:
a superlens layer in contact with the photoresist layer;
a light permissive mask layer transparent to the predetermined light wavelength and having a layer of nanopatterned opaque features formed thereon; and
an intermediate layer separating the superlens layer and the light permissive mask layer by a predetermined distance,
wherein the light source is located to radiate light at the predetermined light wavelength on the light permissive layer of the superlens device, and
wherein the layer of nanopatterned opaque features comprise a layer of opaque features with varying height dimensions.

25. The system in accordance with claim 24 wherein the device to be patterned comprises a substrate.

26. The system in accordance with claim 24 wherein the predetermined light wavelength of the light source is an ultraviolet light wavelength.

27. The system in accordance with claim 24 wherein the intermediate layer of the superlens device is index matched to at least the superlens layer.

28. The system in accordance with claim 27 wherein the intermediate layer of the superlens device is index matched to the superlens layer of the superlens device and the photoresist layer formed on the device to be patterned.

29. The system in accordance with claim 24 wherein the intermediate layer has a smoothness predetermined to be a root-mean-square (rms) surface roughness of less than five nanometers and the intermediate layer separates the superlens layer and the light permissive mask layer by a predetermined distance between 0.1 nanometers and 100 nanometers.

30. The system in accordance with claim 24 wherein the superlens layer has a smoothness predetermined to be a root-mean-square (rms) surface roughness of less than three nanometers and a thickness of the superlens layer is between 1 nanometer and 100 nanometers.

31. The system in accordance with claim 24 wherein the superlens device is in vacuum-assisted hard contact with the photoresist layer.
